(19) United States
(12) Patent Application Publication
(10) Pub. No.: US 2008/0079061 A1
(43) Pub. Date: Apr. 3, 2008

(54) Flash memory cell structure for increased program speed and erase speed

(75) Inventors: Meng Ding, Sunnyvale, CA (US); Amol Joshi, Sunnyvale, CA (US); Takashi Orimoto, Sunnyvale, CA (US); Jayendra Bhakta, Sunnyvale, CA (US); Lei Xue, Sunnyvale, CA (US); Satoshi Torii, Kuwana (JP); Robert Bertram Ogle, San Jose, CA (US)

Correspondence Address: FARJAMI & FARJAMI LLP, 26522 LA ALAMEDA AVENUE, SUITE 360, MISSION VIEJO, CA, 92691, US

(73) Assignees: Advanced Micro Devices, Inc.; SPANSION LLC.

(21) Appl. No.: 11/529,166

(22) Filed: Sep. 28, 2006

(51) Int. Cl. H01L 29/792; H01L 21/336

(52) U.S. Cl. 257/324; 438/287; 438/591; 257/411; 257/325

(57) ABSTRACT

According to one exemplary embodiment, a structure, for example a flash memory cell, comprises a transistor gate dielectric stack situated on a semiconductor substrate. The transistor gate dielectric stack includes a bottom oxide layer, a silicon-rich nitride layer situated on the bottom oxide layer, a low silicon-rich nitride layer situated on the silicon-rich nitride layer, and a top oxide layer situated on the low silicon-rich nitride layer. This embodiment results in a nitride based flash memory cell having improved program speed and retention while maintaining a high erase speed. In another embodiment, a flash memory cell may further comprise a high-K dielectric layer situated on the transistor gate dielectric stack.

### TECHNICAL FIELD

The present invention relates generally to the field of semiconductor devices. More particularly, the present invention is related to memory cells in semiconductor devices.

### BACKGROUND ART

Non-volatile memory devices are currently in widespread use in electronic components that require the retention of information when electrical power is terminated. Non-volatile memory devices include read-only-memory (ROM), programmable-read-only memory (PROM), erasable-programmable-read-only-memory (EPROM), and electrically-erasable-programmable-read-only-memory (EEPROM) devices. EEPROM devices differ from other non-volatile memory devices in that they can be electrically programmed and erased. Flash memory devices are similar to EEPROM devices in that memory cells can be programmed and erased electrically.

Product development efforts in flash memory devices have focused on increasing the program speed, lowering program and read voltages, increasing data retention time, reducing cell erasure times, reducing cell dimensions, and optimizing dielectric materials used in memory cells. Traditional flash memory cells utilizing floating gate technology include a thin gate oxide layer, also referred to as a tunnel oxide layer, situated between a floating gate and a silicon substrate.

Nitride based flash memory cells provide an advanced structure where a charge is stored locally in a nitride layer located between two oxide layers. Nitride based flash memory cells can be more scalable than traditional floating gate cells. However, the erase speed of nitride based memory is intrinsically low since trapped electrons cannot move easily from the nitride layer to the nitride/oxide interface and to the silicon surface. Previous attempts in improving erase speeds have adversely affected the program speed and retention, since programming requires that electrons be quickly trapped and retained by the nitride layer.

### SUMMARY

The present invention is directed to a flash memory cell structure for increased program speed and erase speed. The present invention addresses and resolves the need in the art for a nitride based flash memory cell having improved program speed and retention while maintaining a high erase speed.

According to one exemplary embodiment, the invention's structure, for example a flash memory cell, comprises a transistor gate dielectric stack situated on a semiconductor substrate. The transistor gate dielectric stack includes a bottom oxide layer, a silicon-rich nitride layer situated on the bottom oxide layer, a low silicon-rich nitride layer situated on the silicon-rich nitride layer, and a top oxide layer situated on the low silicon-rich nitride layer. This embodiment of the invention results in a nitride based flash memory cell having improved program speed and retention while maintaining a high erase speed.

In another embodiment, the flash memory cell may further comprise a high-K dielectric layer situated on the transistor gate dielectric stack. In one embodiment, the invention is a method for achieving the above-described flash memory cell structure. In still another embodiment, the invention is a system utilizing the above-described innovative flash memory cell. Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a cross sectional view of a conventional exemplary nitride based flash memory cell.

FIG. 2 illustrates a cross sectional view of a bi-layer nitride based flash memory cell, in accordance with one embodiment of the present invention.

FIG. 3 depicts an exemplary scatter plot comparing program speeds in nitride based memory cells, in accordance with one embodiment of the present invention.

FIG. 4 illustrates a cross sectional view of a bi-layer nitride based flash memory cell comprising a high-K dielectric layer, in accordance with one embodiment of the present invention.

FIG. 5 shows a flowchart illustrating the steps taken to implement an embodiment of the present invention.

FIG. 6 shows a flowchart illustrating the steps taken to implement an embodiment of the present invention.

FIG. 7 illustrates a diagram of an exemplary electronic system including an exemplary chip or die utilizing one or more flash memory cells in accordance with one embodiment of the present invention.

### DETAILED DESCRIPTION OF THE INVENTION

The present invention is directed to a flash memory cell structure for increased program speed and erase speed. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings.

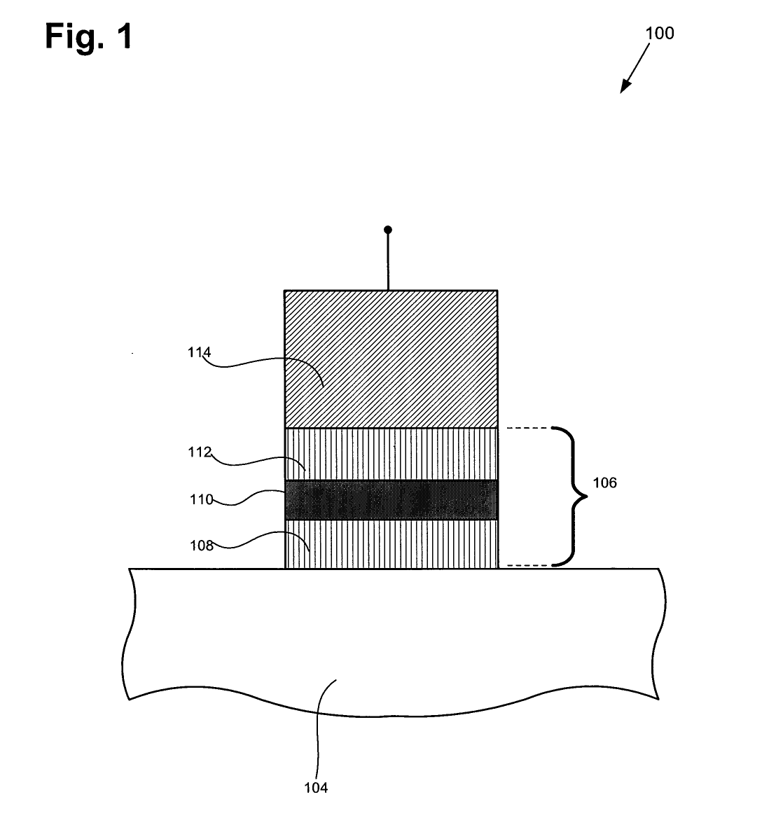

FIG. 1 shows a cross sectional view of an exemplary structure including conventional exemplary nitride based flash memory cell. Structure 100 includes semiconductor substrate 104, transistor gate dielectric stack 106 and control gate 114. Transistor gate dielectric stack 106 is a three-layer structure, comprising bottom oxide layer 108, nitride layer 110 situated over bottom oxide layer 108, and top oxide layer 112 situated over nitride layer 110. Bottom oxide layer 108 and top oxide layer 112 can be silicon oxide, which can be sequentially deposited by low pressure chemical vapor deposition (LPCVD) process or thermally grown, and can each have an initial thickness of between approximately 50.0 Angstroms and approximately 100.0 Angstroms. Nitride layer 110 can be silicon nitride, which can be sequentially deposited by LPCVD process, and can have an initial thickness of between approximately 40.0 Angstroms and approximately 80.0 Angstroms. Also shown in FIG. 1, control gate 114 is situated over transistor gate dielectric stack 106. Control gate 114 can be polycrystalline silicon (also referred to as polysilicon), which can be deposited in an LPCVD process.

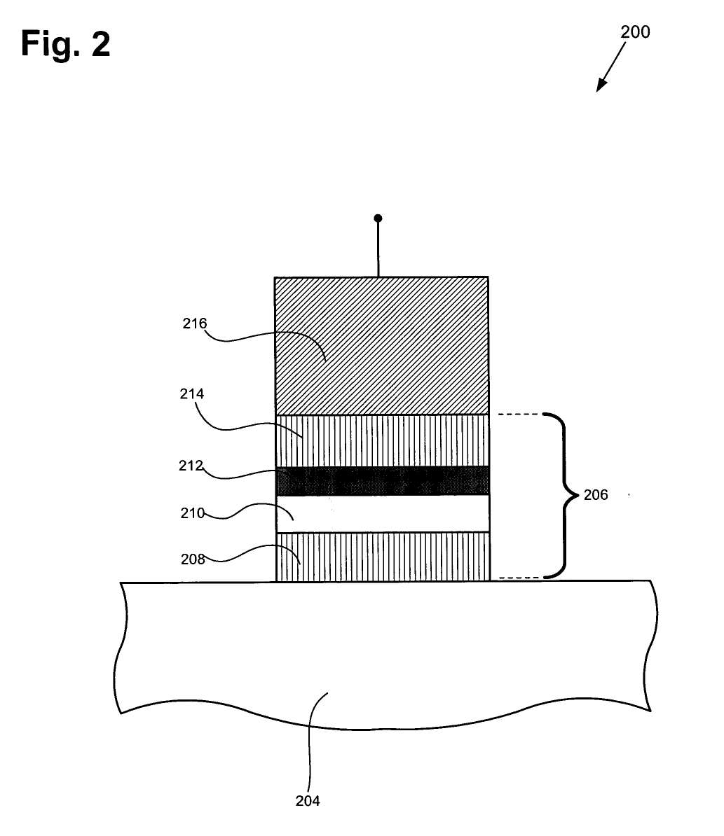

FIG. 2 illustrates a cross sectional view of an exemplary structure including an exemplary flash memory cell in accordance with one embodiment of the present invention. Structure 200 (also referred to as a “flash memory cell” in this application) includes transistor gate dielectric stack 206 that is situated over semiconductor substrate 204. Transistor gate dielectric stack 206 comprises bottom oxide layer 208, silicon-rich nitride layer 210, low silicon-rich nitride layer 212, and top oxide layer 214. Structure 200 further includes control gate 216 situated over transistor gate dielectric stack 206. Semiconductor substrate 204 can be a P-type or an N-type substrate.

Bottom oxide layer 208 and top oxide layer 214 can be silicon oxide, which can be sequentially deposited by low pressure chemical vapor deposition (LPCVD) process or thermally grown, and can each have an initial thickness of between approximately 50.0 Angstroms and approximately 70.0 Angstroms. Silicon-rich nitride layer 210 can be sequentially deposited by LPCVD process and can have an initial thickness of between approximately 40.0 Angstroms and approximately 80.0 Angstroms. According to an embodiment, low silicon-rich nitride layer 212 contains a lower concentration of silicon than silicon-rich nitride layer 210. In another embodiment, layer 212 can comprise an ordinary silicon nitride layer (also referred to simply as “nitride” in this application), instead of the low silicon-rich nitride layer referred to in the earlier embodiment. However, in both embodiments, layer 210 comprises a silicon-rich nitride layer. Low silicon-rich nitride layer 212 can be sequentially deposited by LPCVD process and can have an initial thickness of between approximately 30.0 Angstroms and approximately 60.0 Angstroms.

Also shown in FIG. 2, control gate 216 is situated over transistor gate dielectric stack 206. Control gate 216 can comprise N-type or P-type polycrystalline silicon (also referred to as polysilicon), which can be deposited in an LPCVD process. In one embodiment, structure 200 is a flash memory cell that can store one bit of data. In other embodiments, structure 200 is a flash memory cell that can store two bits of data.

According to the present invention, silicon-rich nitride layer 210 is utilized as a charge trapping layer, resulting in a significant improvement in the erase speed by increasing electron mobility. Forming a low silicon-rich nitride layer 212 over silicon-rich nitride layer 210 effectively slows down or blocks the movement of captured electrons from silicon-rich nitride layer 210 towards top oxide layer 214, which advantageously enhances the program speed of a flash memory cell, and reduces leakage current—thus increasing data retention. Moreover, the program speed is also improved due to greater number of charge trapping states present in silicon-rich nitride layer 210.

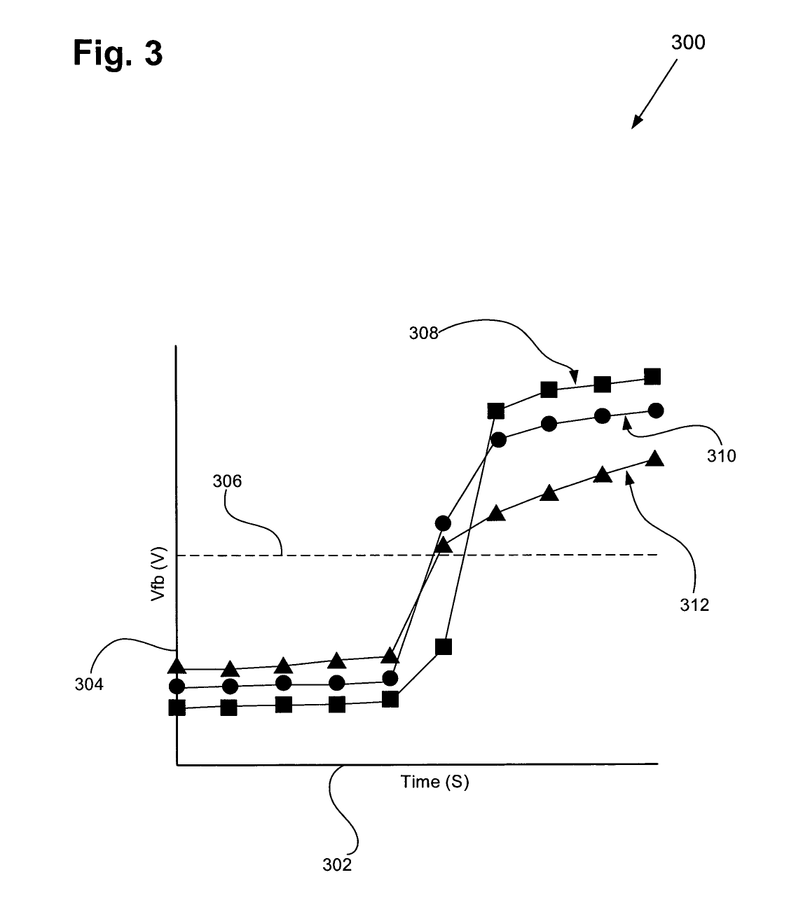

FIG. 3 shows an exemplary scatter plot comparing program speeds in nitride based memory cells, in accordance with the present invention. Scatter plot 300 includes time axis 302 representing time in seconds, flat-band voltage axis 304 representing flat band voltage “Vfb” in volts, zero voltage line 306 (i.e., where Vfb=0 volts), bi-layer plot 308 comprising a very low silicon-rich nitride (for example, a regular nitride layer) over a silicon-rich nitride layer, bi-layer plot 310 comprising a low silicon-rich nitride layer over a silicon-rich nitride layer, and single layer plot 312, comprising only silicon-rich nitride layer.

As shown in FIG. 3, regular nitride bi-layer plot 308 (i.e., the plot marked with squares) displays the program speed of one embodiment of structure 200 described above in FIG. 2. In particular, regular nitride bi-layer plot 308 displays the program speed of a flash memory cell comprising a bottom oxide layer, a silicon-rich nitride layer situated on the bottom oxide layer, a regular nitride layer situated on the silicon-rich nitride layer, and a top oxide layer situated on the regular nitride layer. Also as shown in FIG. 3, low silicon-rich nitride bi-layer plot 310 (i.e., the plot marked with circles) displays the program speed of another embodiment of the structure described above in FIG. 2. In particular, low silicon-rich nitride bi-layer plot 308 displays the program speed of a flash memory cell comprising a bottom oxide layer, a silicon-rich nitride layer situated on the bottom oxide layer, a low silicon-rich nitride layer, i.e. a low silicon-rich nitride layer having a lower silicon concentration than the silicon-rich nitride layer, situated on the silicon-rich nitride layer, and a top oxide layer situated on the low silicon-rich nitride layer.

Also as shown in FIG. 3, silicon-rich nitride single layer plot 312 (i.e., the plot marked with triangles) displays the program speed of a flash memory cell comprising a bottom oxide layer, a single silicon-rich nitride layer situated over the bottom oxide layer, and a top oxide layer situated over the silicon-rich nitride layer.

FIG. 3 shows that the invention's bi-layer structure, i.e. low silicon-rich nitride layer 212 situated on silicon-rich nitride layer 210, advantageously enhances the program speed. As shown in FIG. 3, regular nitride bi-layer plot 308 can be programmed to the highest level above zero voltage line 306 in the shortest amount of time. Low silicon-rich nitride bi-layer plot 310 also has a much higher program speed than silicon-rich nitride single layer plot 312. Thus, scatter plot 300 illustrates that the present invention advantageously provides a significantly higher program speed than a single layer nitride based memory cell.

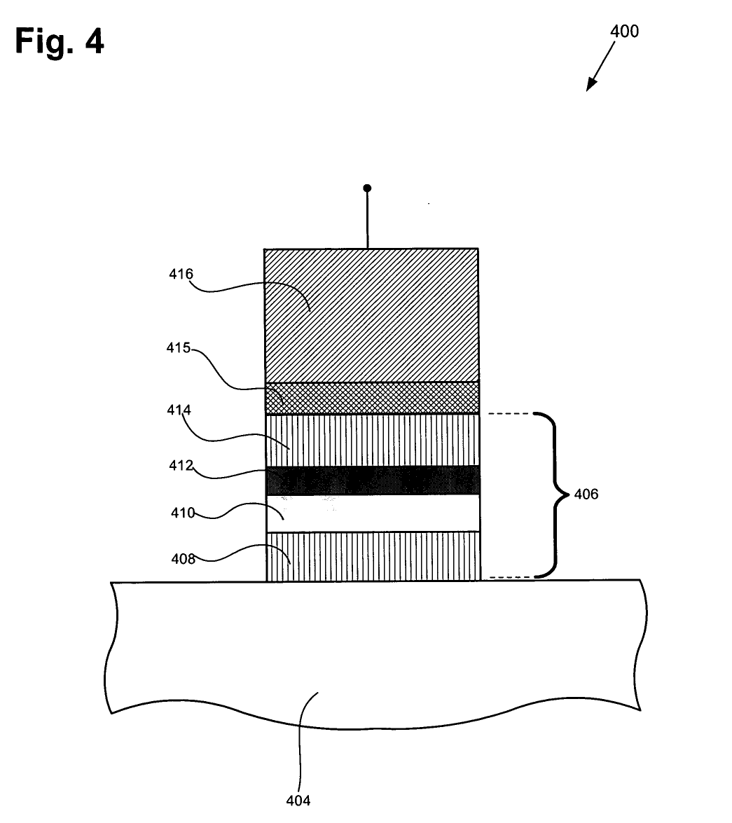

FIG. 4 illustrates a cross sectional view of an exemplary structure including an exemplary flash memory cell in accordance with another embodiment of the present invention. Structure 400 (also referred to as a “flash memory cell” in the present application) includes semiconductor substrate 404 and transistor gate dielectric stack 406 situated over semiconductor substrate 404. Transistor gate dielectric stack 406 comprises bottom oxide layer 408, silicon-rich nitride layer 410, low silicon-rich nitride layer 412, and top oxide layer 414. Flash memory cell 400 further includes high-K dielectric layer 415 situated on transistor gate dielectric stack 406 and control gate 416 situated on high-K dielectric layer 415. Semiconductor substrate 204 can be a P-type or N-type substrate.

Bottom oxide layer 408 and top oxide layer 414 can be silicon oxide, which can be sequentially deposited by low pressure chemical vapor deposition (LPCVD) process or thermally grown, and can each have an initial thickness of between approximately 50.0 Angstroms and approximately 70.0 Angstroms. Silicon-rich nitride layer 410 can be sequentially deposited by LPCVD process and can have an initial thickness of between approximately 40.0 Angstroms and approximately 80.0 Angstroms. Low silicon-rich nitride layer 412 can contain a lower concentration of silicon than silicon-rich nitride layer 410. In another embodiment, low silicon-rich nitride layer 412 can be a regular nitride layer. Low silicon-rich nitride layer 412 can be sequentially deposited by LPCVD process and can have an initial thickness of between approximately 30.0 Angstroms and approximately 60.0 Angstroms.

As shown in FIG. 4, high-K dielectric layer 415 is situated over transistor gate dielectric stack 406. High-K dielectric layer 415 is a dielectric layer with a high dielectric constant and can comprise aluminum oxide (“Al₂O₃”), zirconium oxide (“ZrO₂”), or hafnium oxide (“HfO₂”), as examples. High-K dielectric layer 415 can be deposited in an LPCVD process, for example. Control gate 416 can comprise N-type or P-type polycrystalline silicon (also referred to as polysilicon), which can be deposited in an LPCVD process. In one embodiment, structure 400 is a flash memory cell that can store one bit of data. In other embodiments, structure 400 is a flash memory cell that can store two or more bits of data.

Structure 400, including high-K dielectric layer 415 situated above transistor gate dielectric stack 406, advantageously enhances the erase speed of a flash memory cell without adversely affecting the program speed and data retention. High-K dielectric layer 415 effectively blocks injection of charges from control gate 416 into the charge trapping layer, i.e. into silicon-rich nitride layer 410, thus reducing interference with the erase process and resulting in an improved erase speed. Combined with the bi-layer structure describe above, this embodiment achieves a flash memory cell with greatly improved erase speed and program speed.

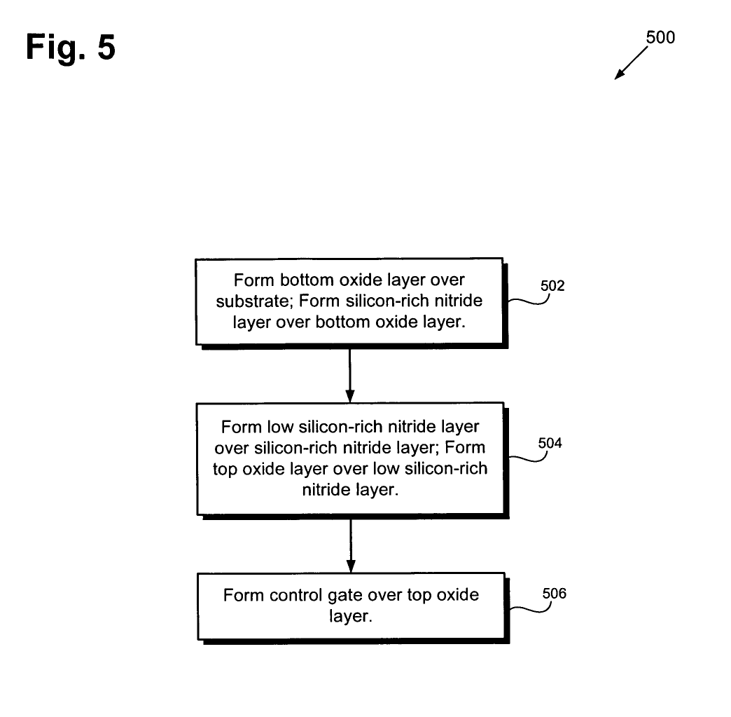

FIG. 5 shows a flowchart illustrating an exemplary method according to an embodiment of the present invention. Certain details and features have been left out of flowchart 500 that are apparent to a person of ordinary skill in the art. For example, a step may consist of one or more substeps or may involve specialized equipment or materials, as known in the art.

Referring now to step 502 of flowchart 500 in FIG. 5, bottom oxide layer 208 in FIG. 2 can be formed over substrate 204 and silicon-rich nitride layer 210 can be formed over bottom oxide layer 208. For example, bottom oxide layer 208 can be deposited by an LPCVD process or thermally grown, and silicon-rich nitride layer 210 can be deposited by an LPCVD process. At step 504 of flowchart 500, low silicon-rich nitride layer 212 is formed over silicon-rich nitride layer 210 and top oxide layer 214 is formed over low silicon-rich nitride layer 212. For example, low silicon-rich nitride layer 212 can be deposited by an LPCVD process and top oxide layer 214 can be deposited by an LPCVD process or thermally grown. In the embodiment of the invention in FIG. 2, low silicon-rich nitride layer 212 contains a lower concentration of silicon than silicon-rich nitride layer 210. At step 506 of flowchart 500, control gate 216 in FIG. 2 is formed over top oxide layer 214. Control gate 216, which can comprise N-type or P-type polysilicon, can be deposited in an LPCVD process, for example.

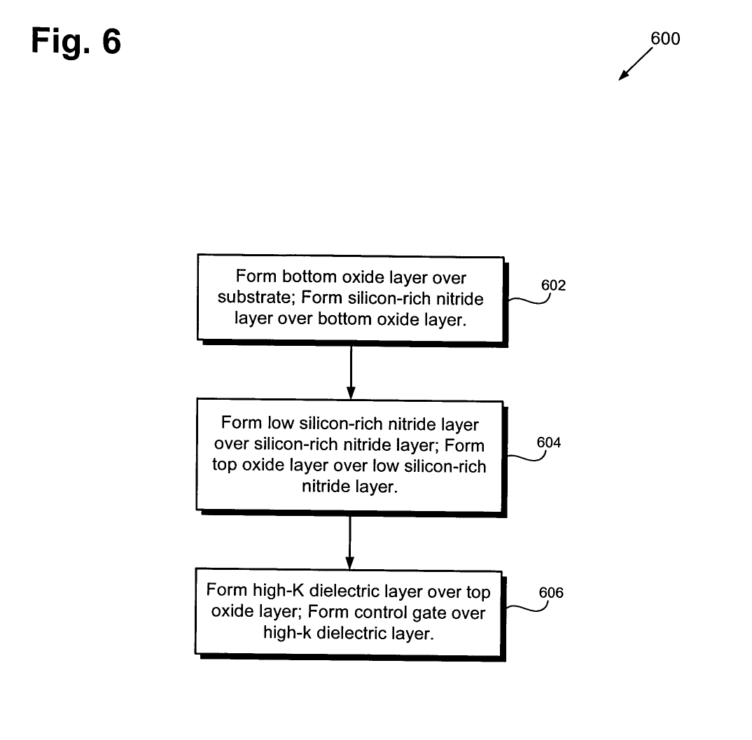

FIG. 6 shows a flowchart illustrating an exemplary method according to an embodiment of the present invention. Certain details and features have been left out of flowchart 600 that are apparent to a person of ordinary skill in the art. For example, a step may consist of one or more substeps or may involve specialized equipment or materials, as known in the art.

Referring now to step 602 of flowchart 600 in FIG. 6, bottom oxide layer 408 in FIG. 4 can be formed over substrate 404 and silicon-rich nitride layer 410 can be formed over bottom oxide layer 408. For example, bottom oxide layer 408 can be deposited by an LPCVD process or thermally grown, and silicon-rich nitride layer 410 can be deposited by an LPCVD process. At step 604 of flowchart 600, low silicon-rich nitride layer 412 is formed over silicon-rich nitride layer 410 and top oxide layer 414 is formed over low silicon-rich nitride layer 412. For example, low silicon-rich nitride layer 412 can be deposited by an LPCVD process and top oxide layer 414 can be deposited by an LPCVD process or thermally grown. In the embodiment of the invention in FIG. 4, low silicon-rich nitride layer 412 contains a lower concentration of silicon than silicon-rich nitride layer 410.

At step 606 of flowchart 600, high-K dielectric layer 415 is formed over top oxide layer 414 and control gate 416 in FIG. 4 is formed over high-K dielectric layer 414. High-K dielectric layer 415 can comprise aluminum oxide, zirconium oxide, or hafnium oxide, for example, and can be deposited in an LPCVD process. Control gate 416, which can comprise N-type or P-type polysilicon, can be deposited in an LPCVD process, for example.

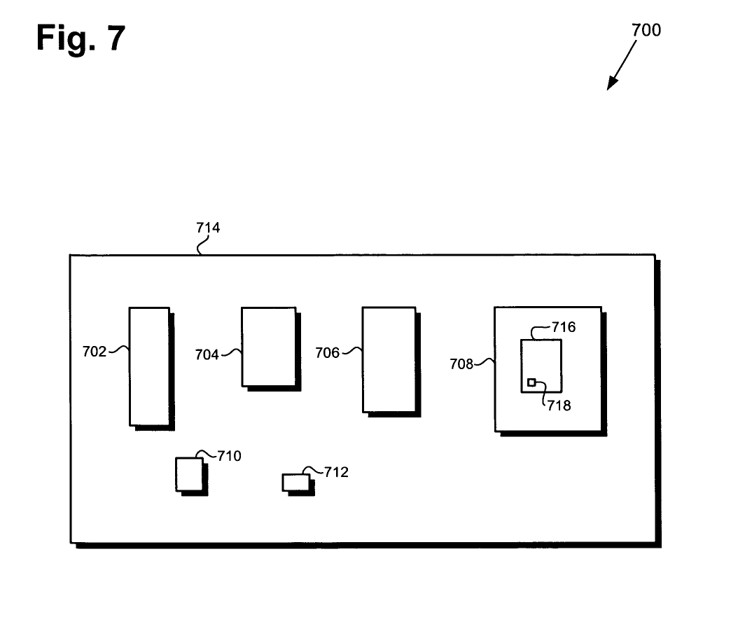

FIG. 7 illustrates a diagram of an exemplary electronic system including an exemplary chip or die utilizing one or more flash memory cells in accordance with one embodiment of the present invention. Electronic system 700 includes exemplary modules 702, 704, and 706, IC chip 708, discrete components 710 and 712, residing in and interconnected through printed circuit board (PCB) 714. In one embodiment, electronic system 700 may include more than one PCB. IC chip 708 includes flash memory array 716, which utilizes one or more flash memory cells designated by numeral 718.

As shown in FIG. 7, modules 702, 704, and 706 are mounted on PCB 714 and can each be, for example, a central processing unit (CPU), a graphics controller, a digital signal processor (DSP), an application specific integrated circuit (ASIC), a video processing module, an audio processing module, an RF receiver, an RF transmitter, an image sensor module, a power control module, an electro-mechanical motor control module, or a field programmable gate array (FPGA), or any other kind of module utilized in modern electronic circuit boards. PCB 714 can include a number of interconnect traces (not shown in FIG. 7) for interconnecting modules 702, 704, and 706, discrete components 710 and 712, and IC chip 708.

Also shown in FIG. 7, IC chip 708 is mounted on PCB 714 and can be, for example, any chip utilizing a flash memory cell. In one embodiment, IC chip 708 may not be mounted on PCB 714, and may be interconnected with other modules on different PCBs. Flash memory array 716 is situated in IC chip 708 and includes one or more flash memory cells 718. Flash memory cell(s) 718 can comprise, for example, a flash memory cell as specified in one of the embodiments of the invention described above. Further shown in FIG. 7, discrete components 710 and 712 are mounted on PCB 714 and can each be, for example, an active filter discrete component, such as one including a BAW or SAW filter or the like, a power amplifier or an operational amplifier, a semiconductor device, such as a transistor or a diode or the like, an antenna element, an inductor, a capacitor, or a resistor.

Electronic system 700 can be, for example, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), digital game playing device, a digital testing and/or measuring device, a digital avionics device, or a digitally-controlled medical device, or in any other kind of module utilized in modern electronics

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

Thus, a flash memory cell with increased program and erase speeds has been described.

1. A structure comprising:
a bottom oxide layer in a transistor gate dielectric stack situated over a semiconductor substrate;
a silicon-rich nitride layer situated over said bottom oxide layer;
a low silicon-rich nitride layer situated over said silicon-rich nitride layer, wherein said low silicon-rich nitride layer contains a lower silicon concentration than said silicon-rich nitride layer.

2. The structure of claim 1 further comprising a top oxide layer situated over said low silicon-rich nitride layer.

3. The structure of claim 2 further comprising a control gate situated over said top oxide layer.

4. The structure of claim 2 further comprising a high-K dielectric layer situated over said top oxide layer.

5. The structure of claim 4 further comprising a control gate situated over said high-K dielectric layer, said control gate being selected from the group consisting of a P-type polysilicon and an N-type polysilicon.

6. The structure of claim 1, wherein said structure is a flash memory cell.

7. The structure of claim 6, wherein said flash memory cell stores two bits of data.

8. A method of forming a flash memory cell, said method comprising steps of:
forming a bottom oxide layer over a semiconductor substrate;
forming a silicon-rich nitride layer over said bottom oxide layer;
forming a low silicon-rich nitride layer over said silicon-rich nitride layer, wherein said low silicon-rich nitride layer contains a lower silicon concentration than said silicon-rich nitride layer.

9. The method of claim 8 further comprising a step of forming a top oxide layer over said low silicon-rich nitride layer.

10. The method of claim 9 further comprising a step of forming a control gate over said top oxide layer.

11. The method of claim 9 further comprising a step of forming a high-K dielectric layer over said top oxide layer.

12. The method of claim 11 further comprising a step of forming a control gate over said high-K dielectric layer.

13. The method of claim 9, wherein said high-K dielectric layer comprises a dielectric selected from the group consisting of aluminum oxide, hafnium oxide, and zirconium oxide.

14. The method of claim 8, wherein said flash memory cell stores two bits of data.

15. An electronic system, including a printed circuit board, said electronic system comprising a die, said die comprising at least one flash memory cell, said at least one flash memory cell comprising:
a bottom oxide layer in a transistor gate dielectric stack situated over a semiconductor substrate;
a silicon-rich nitride layer situated over said bottom oxide layer;
a low silicon-rich nitride layer situated over said silicon-rich nitride layer, wherein said low silicon-rich nitride layer contains a lower silicon concentration than said silicon-rich nitride layer.

16. The electronic system of claim 15, wherein said at least one flash memory cell further comprises a top oxide layer situated over said low silicon-rich nitride layer.

17. The electronic system of claim 16, wherein said at least one flash memory cell further comprises a control gate situated over said top oxide layer.

18. The electronic system of claim 17, wherein said at least one flash memory cell further comprises a high-K dielectric layer situated between said top oxide layer and said control gate.

19. The electronic system of claim 15, wherein said at least one flash memory cell stores two bits of data.

20. The electronic system of claim 15, wherein said electronic system is selected from the group consisting of a wired communications device, a wireless communications device, a cell phone, a switching device, a router, a repeater, a codec, a LAN, a WLAN, a Bluetooth enabled device, a digital camera, a digital audio player and/or recorder, a digital video player and/or recorder, a computer, a monitor, a television set, a satellite set top box, a cable modem, a digital automotive control system, a digitally-controlled home appliance, a printer, a copier, a digital audio or video receiver, an RF transceiver, a personal digital assistant (PDA), a digital game playing device, a digital testing and/or measuring device, a digital avionics device, and a digitally-controlled medical device.
